(19) United States
(12) Patent Application Publication
(10) Pub. No.: US 2014/0069695 A1
(43) Pub. Date: Mar. 13, 2014

(54) Designs and Fabrication Processes of a Heatsink

(71) Applicant: Chang Han, Pleasanton, CA (US)

(72) Inventor: Chang Han, Pleasanton, CA (US)

(73) Assignee: COFAN USA, INC., Fremont, CA (US)

(21) Appl. No.: 13/614,793

(22) Filed: Sep. 13, 2012

(51) Int. Cl. H05K 7/20; H05K 13/00

(52) U.S. Cl. 174/252; 29/592.1

(57) ABSTRACT

A heat sink dissipates heat that is generated by an electronic component on a top surface of a print circuit board. A portion of the print circuit board is removed to expose a portion of bottom surface of the electronic component. The heat sink comprises a heat sink body of a first thermally conductive material and an embossing pattern formed on a first surface of the heat sink body. The embossing pattern includes a surface area that is defined by a perimeter circumscribing the embossing pattern. The embossing pattern is made of a second thermally conductive material and is coupled to the electronic component.

### TECHNICAL FIELD

The example embodiments of the present invention generally relate to methods of improving thermal dissipation on a printed circuit board, and more particularly to designs and fabrication processes of a heat sink.

### BACKGROUND

In electronic systems, a heat sink cools a device by dissipating heat into the surrounding air. Heat sinks are used to cool electronic components such as high-power semiconductor devices, and optoelectronic devices such as higher-power lasers and light emitting devices. FIG. 1 shows a side-view of a printed circuit board module 100. In the printed circuit board module 100, a light emitting device package 102 is mounted on a top surface of a printed circuit board 104. A heat sink 106 is located under the printed circuit board 104 to conduct heat away from the light emitting device package 102. With such a structure, heat generated by the light emitting device package 102 propagates through the printed circuit board 104 and is then dissipated by the heat sink 106 to the ambient. However, due to the relatively high thermal resistance of the printed circuit board materials, the thermal dissipation from the light emitting device package 102 to the heat sink 106 may be insufficient. The insufficient thermal dissipation may result in overheating which may cause severe performance degradation or permanent damage to the printed circuit board module 100.

FIG. 2 shows a typical structure of the printed circuit board 104 that is illustrated in FIG. 1. The printed circuit board 104 includes four layers: a first layer serving as a substrate 202, a second layer 204 (e.g., a layer including prepreg) deposited on the substrate 202, a third layer 206 (e.g., a layer including copper foil or a.k.a.) deposited on the second layer 204, and a fourth layer 208 (e.g., a layer including solder mask) deposited on the third layer 206. The substrate 202 may comprise FR-4, a composite material composed of woven fiberglass epoxy. The second layer 204 may also include FR-4 and may be used as dielectric adhesive between the substrate 202 and the third layer 206. The third layer 206 may be used to form circuit traces which are covered by the fourth layer 208. The heat generated by the light emitting device package 102 (shown in FIG. 1) is conducted through the second layer 204 and the substrate 202 prior to reaching the heat sink 106 (shown in FIG. 1). The efficiency of thermal dissipation may be reduced due to the high thermal resistance of the second layer 204 and the substrate 202.

BRIEF SUMMARY

According to one exemplary embodiment of the present invention, a heat sink to dissipate heat that is generated by an electronic component on a top surface of a print circuit board is described. A portion of the print circuit board is removed to expose a portion of bottom surface of the electronic component. The heat sink comprises a heat sink body of a first thermally conductive material and an embossing pattern formed on a first surface of the heat sink body. The embossing pattern includes a surface area that is defined by a perimeter circumscribing the embossing pattern. The embossing pattern is made of a second thermally conductive material and is coupled to the electronic component.

According to one exemplary embodiment of the present invention, a method of fabricating a heat sink to dissipate heat that is generated by an electronic component on a top surface of a print circuit board is described. A portion of the print circuit board is removed to expose a portion of bottom surface of the electronic component. The method comprises providing a heat sink body of a first thermally conductive material, creating a raised area on a first surface of the heat sink body, and forming an embossing pattern on the first surface of the heat sink body. The embossing pattern includes a surface area that is defined by a perimeter circumscribing the embossing pattern. The embossing pattern is made of a second thermally conductive material and in contact with the electronic component.

### BRIEF DESCRIPTION OF THE DRAWING(S)

Having thus described the example embodiments of the present invention in general terms, reference will now be made to the accompanying drawings, which are not necessarily drawn to scale, and wherein:

FIG. 1 illustrates a side-view of a printed circuit board module of the prior art;

FIG. 2 illustrates a typical structure of the printed circuit board that is illustrated in FIG. 1;

FIG. 3(a) illustrates a heat sink according to an example embodiment of the present invention;

FIGS. 3(b)-3(d) illustrate different views of the heat sink illustrated in FIG. 3(a);

FIG. 4(a) illustrates penetrating cuts formed on a heat sink body according to an example embodiment of the present invention;

FIG. 4(b) illustrates a heat sink according to an example embodiment of the present invention;

FIGS. 4(c)-4(d) illustrate different views of the heat sink illustrated in FIG. 4(b);

FIG. 5(a) illustrates a penetrating cut formed on a heat sink body according to an example embodiment of the present invention;

FIG. 5(b) illustrates a heat sink according to an example embodiment of the present invention;

FIGS. 5(c)-5(d) illustrate different views of the heat sink illustrated in FIG. 5(b);

FIG. 6(a) illustrates example embossing patterns according to an example embodiment of the present invention;

FIG. 6(b) illustrates a heat sink according to an example embodiment of the present invention;

FIG. 6(c) illustrates a side view of the heat sink that includes the example embossing pattern illustrated in FIG. 6(a); and

FIGS. 7(a)-(c) are cross-sectional views of assembling an example heat sink with a print circuit board according to an example embodiment of the present invention.

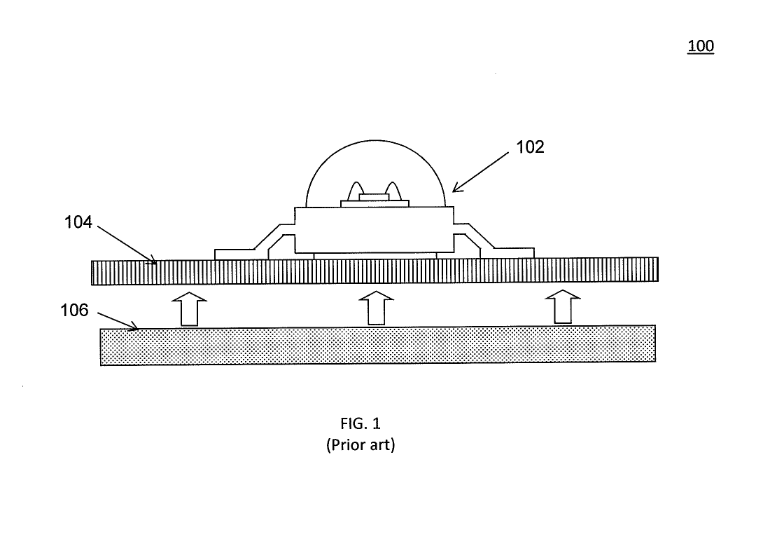

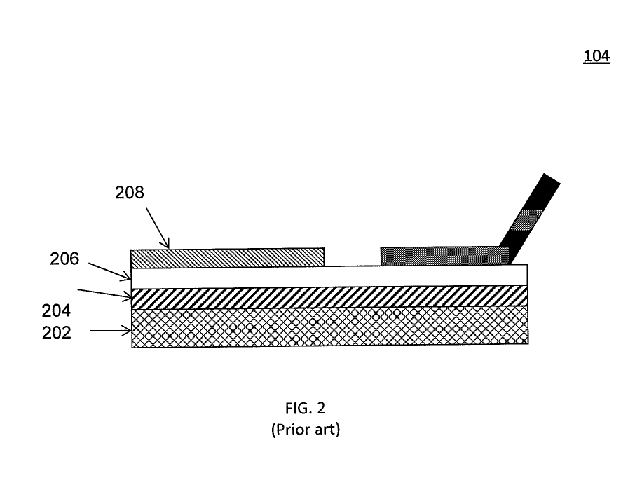

### DETAILED DESCRIPTION

The present disclosure now will be described more fully with reference to the accompanying drawings, in which some, but not all embodiments of the disclosure are shown. This disclosure may be embodied in many different forms and should not be construed as limited to the embodiments set forth; rather, these example embodiments are provided so that this disclosure will be thorough and complete, and will fully convey the scope of the disclosure to those skilled in the art. Like numbers refer to like elements throughout.

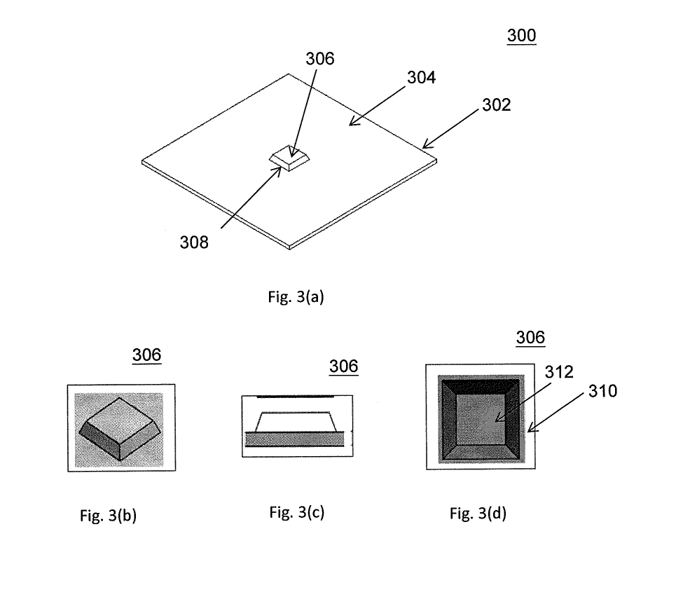

FIG. 3(a) illustrates a heat sink 300 according to an example embodiment of the present invention. FIGS. 3(b)-3(d) illustrate different views of the heat sink 300 illustrated in FIG. 3(a). The heat sink 300 comprises a heat sink body 302. The heat sink 300 may have a first surface 304 and may further comprise an embossing pattern 306 formed on the first surface 304. To increase the dielectric strength, an anodized layer (not shown) may be generated on the first surface 304 by electrolyte passivation process to oxidize the first surface 304. The embossing pattern 306 may have a surface area 308 that is defined by a perimeter circumscribing the embossing pattern 306 on the first surface 304. The surface area 308 may be in form of circle, square, rectangle or polygon. The heat sink body 302 may be made of a first thermally conductive material comprising at least one of aluminum, copper, graphite or metal alloy. The embossing pattern 306 may be made of a second thermally conductive material comprising at least one of aluminum, copper, graphite or metal alloy. The second thermally conductive material may or may not be the same as that of the heat sink body 302. FIGS. 3(b) and 3(c) illustrate a 3D view and a side-view of the embossing pattern 306 respectively. To form the embossing pattern 306, a press may be applied against a second surface 310 of the heat sink body 302 to create a raised area on the first surface 304. In this embodiment, the raised area may be the embossing pattern 306. The press may be applied by a stamping process that may include a variety of operations, such as punching and embossing. The stamping process may include mechanical presses or hydraulic presses. A bottom view of the embossing pattern 306 is illustrated in FIG. 3(d). A depressed area 312 corresponding to the embossing pattern 306 is formed due to the stamping process.

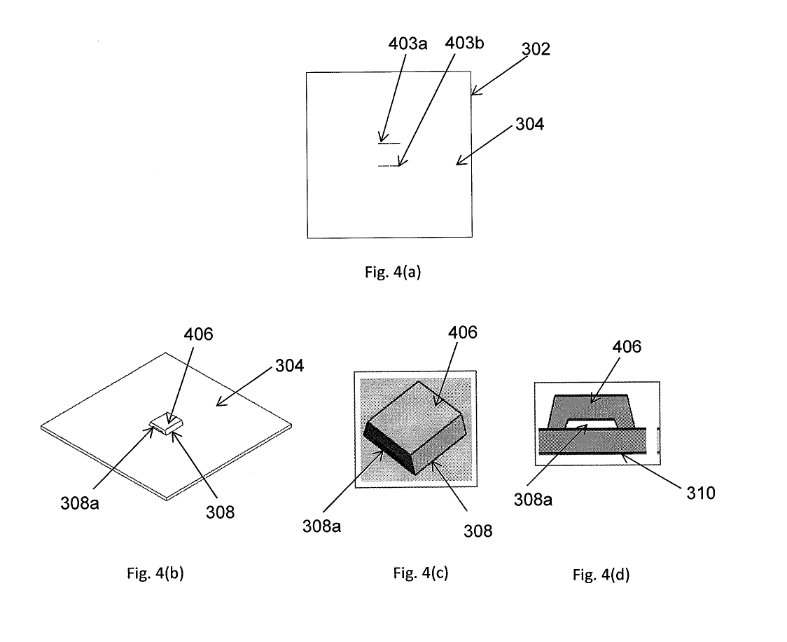

The embossing pattern may vary depending on various applications. With reference to FIGS. 4(a)-4(d), two penetrating cuts 403a and 403b are formed on the heat sink body 302 prior to applying the press against the second surface 310 of the heat sink body 302. By applying the stamping press, a raised area is created on the first surface 304 to form a rectangular embossing pattern 406 on the first surface 304. The surface area 308 defined by the perimeter circumscribing the rectangular embossing pattern 406 on the first surface 304 may be a rectangle. The two penetrating cuts 403a and 403b are on the opposing sides of the rectangle. The penetrating cuts 403a and 403b may allow two portions of the surface area 308 to be discontinuous on the surface area 308. A discontinuous portion 308a resulting from one of the penetrating cuts 403a and 403b is shown in FIGS. 4(b)-4(d).

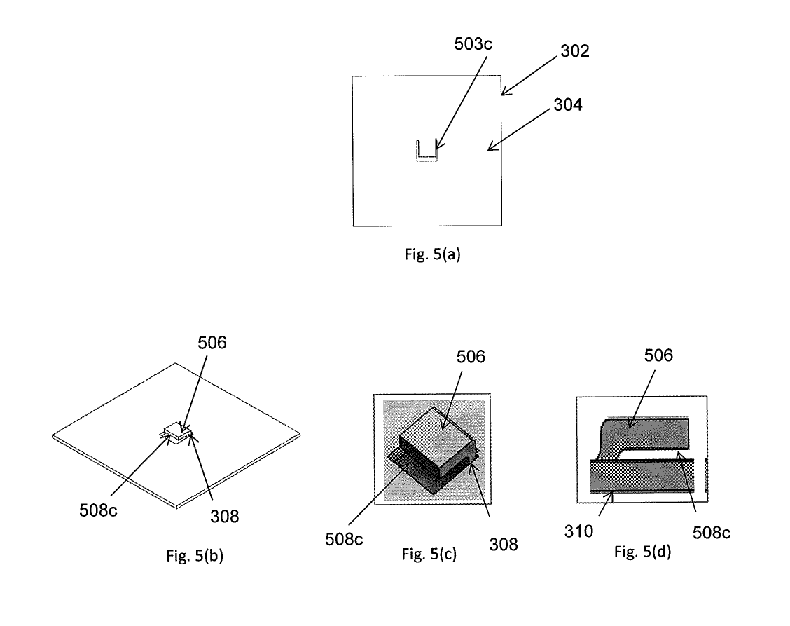

With reference to FIGS. 5(a)-5(d), a U-shape penetrating cut 503c is formed on the heat sink body 302 prior to applying the press against the second surface 310 of the heat sink body 302. By applying the stamping press, a raised area is created on the first surface 304 to form a rectangular embossing pattern 506 on the first surface 304. The surface area 308 defined by the perimeter circumscribing the rectangular embossing pattern 506 on the first surface 304 may be a rectangle. The penetrating cut 503c may be three sides of the rectangle thus allowing a portion of the surface area 308 to be discontinuous on the surface area 308. The discontinuous portion 508c resulting from the penetrating cut 503c is shown in FIGS. 5(b)-5(d).

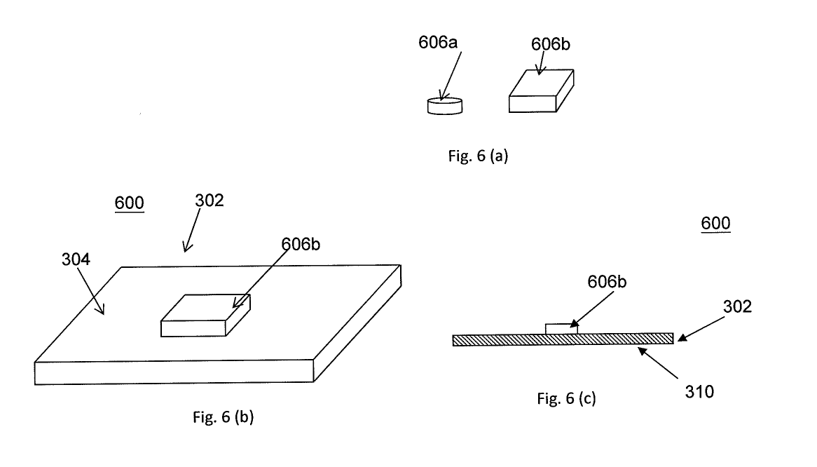

In an embodiment illustrated in FIGS. 6(a)-6(c), the raised area on the first surface 304 may be not created by applying a stamping process. In this embodiment, the raised area may be created by attaching an embossing element to the first surface 304 of the heat sink body 302 to form an embossing pattern. Although FIG. 6(a) only illustrates a cylinder embossing element 606a and a rectangular embossing element 606b, a person of ordinary skill in the art should understand that the embossing element may also be in form of cube or polyhedron. The perimeter circumscribing the embossing pattern on the first surface 304 may be in form of circle, square, rectangle or polygon. FIG. 6(b) illustrates a heat sink 600 having the rectangular embossing element 606b attached to the first surface 304 of the heat sink body 302 to form the embossing pattern. FIG. 6(c) illustrates a side-view of the heat sink 600 including the rectangular embossing element 606b. Because the embossing pattern is formed by attaching an embossing element to the heat sink body, the first thermally conductive material of the heat sink body 302 may or may not be the same as the second thermally conductive material of the embossing pattern.

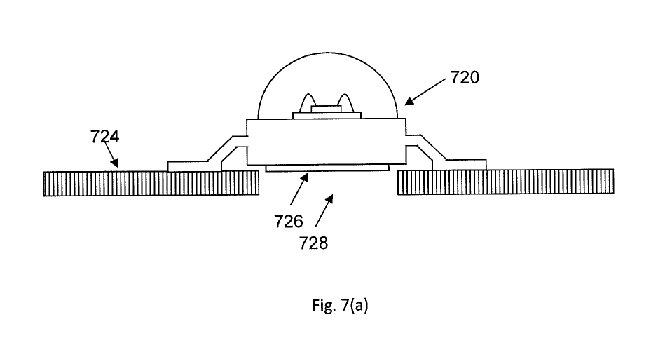

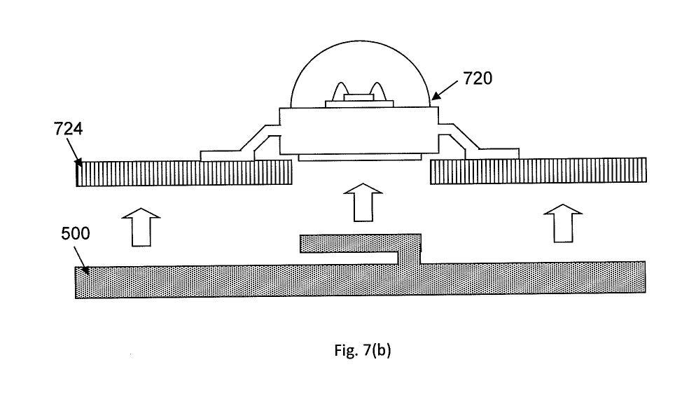

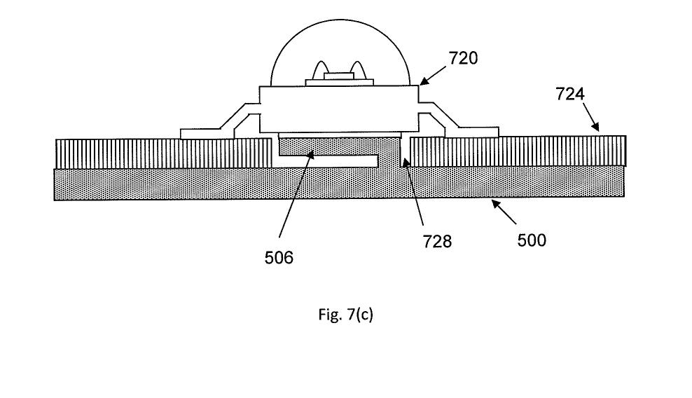

FIGS. 7(a)-(c) are cross-sectional views of assembling an example heat sink with a print circuit board according to an example embodiment of the present invention. In FIG. 7(a), a heat-generating electronic component 720 is mounted on a top surface of a printed circuit board 724. A portion of the printed circuit board is removed to expose a portion of bottom surface 726 of the electronic component 720. The removal may be performed by mechanical punch, drilling, carving, chemical etching or any suitable methods. A space 728 is then formed under the exposed bottom surface 726. The size and shape of the space 728 may vary depending on the embossing pattern. FIG. 7(b) shows an example assembly using the heat sink 500 that includes a U-shape cutting on the heat sink body which is illustrated in FIGS. 5(a)-5(d). A person of ordinary skill in the art should understand that the heat sink is not limited to the heat sink described in FIGS. 5(a)-5(d) but may be any exemplary heat sink described above. Referring to FIG. 7(c), the embossing pattern 506 is then placed in the space 728 to allow the embossing pattern 506 to be coupled to the electronic component 720 directly. The embossing pattern 506 may also be coupled to the electronic component through one of solder, solder paste or thermal-conductive epoxy to improve the adhesion and thermal resistance.

Many modifications and other example embodiments set forth herein will come to mind to one skilled in the art to which these example embodiments pertain having the benefit of the teachings presented in the foregoing descriptions and the associated drawings. Therefore, it is to be understood that the embodiments are not to be limited to the specific ones disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims. Although specific terms are employed herein, they are used in a generic and descriptive sense only and not for purposes of limitation.

That which is claimed:

1. A heat sink to dissipate heat that is generated by an electronic component on a top surface of a print circuit board, a portion of the print circuit board being removed to expose a portion of bottom surface of the electronic component, the heat sink comprising:
a heat sink body of a first thermally conductive material; and
an embossing pattern formed on a first surface of the heat sink body, the embossing pattern including a surface area that is defined by a perimeter circumscribing the embossing pattern on the first surface, wherein the embossing pattern is made of a second thermally conductive material and coupled to the electronic component.

2. The heat sink of claim 1, wherein the embossing pattern is formed by applying a press against a second surface of the heat sink body to create a raised area on the first surface of the heat sink body to form the embossing pattern.

3. The heat sink of claim 1, wherein the embossing pattern is formed by attaching an element to the first surface of the heat sink body.

4. The heat sink of claim 1, wherein the surface area of the embossing pattern comprises at least one of circle, square, rectangle and polygon.

5. The heat sink of claim 1, wherein the surface area comprises one or more discrete portions that allows the perimeter to be discontinuous on the surface area.

6. The heat sink of claim 5, wherein the discrete portion comprises a U shape.

7. The heat sink of claim 5, wherein the discrete portions comprise two parallel lines.

8. The heat sink of claim 1, wherein the first thermally conductive material comprises at least one of aluminum, copper, graphite and metal alloy.

9. The heat sink of claim 1, wherein the second thermally conductive material comprises at least one of aluminum, copper, and metal alloy.

10. The heat sink of claim 1, wherein the heat sink body comprises an anodized layer on the first surface.

11. The heat sink of claim 1, wherein the embossing pattern is coupled to the electronic component through one of solder, solder paste or thermal-conductive epoxy.

12. A method of fabricating a heat sink to dissipate heat that is generated by an electronic component on a top surface of a print circuit board, a portion of the print circuit board being removed to expose a portion of bottom surface of the electronic component, the method comprising:
providing a heat sink body of a first thermally conductive material;
creating a raised area on a first surface of the heat sink body;
forming an embossing pattern on the first surface of the heat sink body, the embossing pattern including a surface area that is defined by a perimeter circumscribing the embossing pattern on the first surface, wherein the embossing pattern is made of a second thermally conductive material and in contact with the electronic component.

13. The method of claim 12, further comprising forming one or more penetrating cuts on the heat sink body prior to creating a raised area to allow one or more portions on the surface area to be discontinuous on the surface area.

14. The method of claim 12, further comprising applying a press against a second surface of the heat sink body to create the raised area on the first surface.

15. The method of claim 12, further comprising attaching an embossing element to the first surface of the heat sink body to create the raised area on the first surface.

16. The method of claim 12, further comprising generating an anodized layer on the first surface of the heat sink body.
